(19) United States
(12) Patent Application Publication
(10) Pub. No.: US 2008/0048277 A1
(43) Pub. Date: Feb. 28, 2008

(54) Gate of a transistor and method of forming the same

(75) Inventors: Jin-Gyun Kim, Yongin-si (KR); Ki-Hyun Hwang, Seongnam-si (KR); Sang-Ryol Yang, Hwaseong-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/892,223

(22) Filed: Aug. 21, 2007

(30) Foreign Application Priority Data
Aug. 22, 2006 (KR) 10-2006-0079422

(51) Int. Cl. H01L 29/40; H01L 21/3205

(52) U.S. Cl. 257/412; 257/751; 438/592; 257/E29.111; 257/E21.294

(57) ABSTRACT

A gate of a transistor includes a gate oxide layer formed on a semiconductor device, a first conductive layer pattern including polysilicon doped with boron and formed on the gate oxide layer, a diffusion preventing layer pattern including amorphous silicon formed by a chemical vapor deposition process using a reaction gas having trisilane (Si₃H₈) and formed on the first conductive layer pattern, and a second conductive layer pattern including metal silicide and formed on the diffusion preventing layer pattern. Since a gate of PMOS transistor includes a diffusion preventing layer having an excellent surface morphology, diffusion of impurities is sufficiently prevented. Thus, the threshold voltage of PMOS transistor may be reduced and threshold voltage distribution may be improved.

### PRIORITY STATEMENT

This application claims priority under 35 USC § 119 to Korean Patent Application No. 10-2006-0079422, filed on Aug. 22, 2006, in the Korean Intellectual Property Office (KIPO), the entire contents of which are herein incorporated by reference.

### BACKGROUND

1. Field

Example embodiments relate to a gate of a transistor and a method of forming the same, for example to a gate of a PMOS transistor and a method of forming the gate.

2. Description of Related Art

In conventional processes for manufacturing a semiconductor device, polysilicon doped with n-type impurities, such as phosphorous, antimony, etc., may be used as a gate electrode for either, a positive channel metal oxide semiconductor (PMOS) transistor or a negative channel metal oxide semiconductor (NMOS) transistor.

However, since a buried channel may be formed in a PMOS transistor that uses polysilicon doped with n-type impurities as the gate electrode, such a PMOS transistor may have a high threshold voltage that may greatly increase electric power consumption. Accordingly, a buried channel type PMOS transistor including polysilicon doped with n-type impurities may not sufficiently meet the required characteristics of a semiconductor device, such as achieving high operation performance with relatively low energy consumption.

Thus, a surface channel type PMOS transistor having a low operation voltage but a high operation velocity may be required. A NMOS transistor may require a gate electrode including polysilicon doped with n-type impurities and a PMOS transistor may require a gate electrode including polysilicon doped with p-type impurities.

A surface channel type PMOS transistor may have a gate structure in which a gate oxide layer, a polysilicon pattern and a metal silicide pattern may be stacked on one another. A polysilicon pattern may be formed on the gate oxide layer and may be doped with p-type impurities such as boron, for example. Such a metal silicide pattern may have a resistance lower than that of a polysilicon pattern.

On the other hand, in order to form the polysilicon pattern doped with boron, for example, a material including boron may be implanted into undoped polysilicon or polysilicon doped with n-type impurities.

However, boron ions may diffuse faster than n-type impurities, such as phosphorous ions, at substantially the same temperature. In particular, boron ions may diffuse faster through a grain boundary than through the grain in a thin film. Also, the boron ions diffuse faster in the metal silicide pattern formed on a polysilicon pattern than within a polysilicon pattern.

Thus, when boron ions diffuse into a metal silicide pattern through the grain and the grain boundary within the polysilicon pattern, insufficient numbers of such ions may remain in the polysilicon pattern, such that the absolute value of the threshold voltage of a p-type transistor may be increased. Additionally, because the boron ions may not diffuse uniformly, the threshold voltage distribution of a p-type transistor may become irregular.

### SUMMARY

Example embodiments are directed to a gate having a structure for preventing boron ions and the like from diffusing into an upper layer, as well as to methods of forming such a gate.

According to example embodiments, a gate of a transistor in accordance with the present invention may include a gate oxide layer, a first conductive layer, a diffusion preventing layer and a second conductive layer. The gate oxide layer may be formed on a semiconductor device. The first conductive layer pattern may be formed on the gate oxide layer. Further, the first conductive layer may include polysilicon doped with boron. The diffusion preventing layer pattern may be formed on the first conductive layer and may include amorphous silicon formed by chemical vapor deposition (CVD) or a similar process using a reaction gas that may include trisilane (Si₃H₈). The second conductive layer pattern including metal silicide may be formed on the diffusion preventing layer pattern. The metal silicide may include tungsten silicide.

In example embodiments, the root-mean-square surface roughness of the diffusion preventing layer pattern may be less than about 3. The diffusion preventing layer pattern may have a thickness of about 10 Å to about 100 Å.

According to at least one example embodiment, in a method of forming a transistor gate, a gate oxide layer may be formed on a semiconductor substrate. A first conductive layer including polysilicon doped with boron may be formed on the gate oxide layer. A diffusion preventing layer that may include amorphous silicon may be formed on the first conductive layer by chemical vapor deposition (CVD) or a similar process, using a reaction gas that may include trisilane (Si₃H₈). A second conductive layer including metal silicide may be formed on the diffusion preventing layer. The second conductive layer, the diffusion preventing layer, and the first conductive layer may be patterned to form a gate electrode structure.

In at least one example embodiment, the surface root-mean-square roughness of the diffusion preventing layer may be less than about 3. The diffusion preventing layer may have a thickness of about 10 Å to about 100 Å. Undoped materials may be deposited to form the diffusion preventing layer. The diffusion preventing layer may be formed at a temperature of about 400° C. to about 600° C.

According to at least one example embodiment, in a method of forming a gate of a transistor, a gate oxide layer may be formed on a semiconductor substrate that may be divided into a first region and a second region. A preliminary first conductive layer including polysilicon doped with n-type impurities may be formed on the gate oxide layer. Boron ions may be implanted into the preliminary first conductive layer in the second region to form a first conductive layer. A diffusion preventing layer, including amorphous silicon, may be formed on the first conductive layer by a CVD process using a reaction gas that may include trisilane (Si₃H₈). A second conductive layer, that may include metal silicide, may be formed on the diffusion preventing layer. The second conductive layer, the diffusion preventing layer, and the first conductive layer may be patterned to form a first gate electrode structure including polysilicon doped with n-type impurities in the first region and a second gate electrode structure including polysilicon doped with boron or similar impurities in the second region.

According to at least one example embodiment, the diffusion preventing layer may have a thickness of about 10 Å to about 100 Å. Root-mean-square roughness of a surface of the diffusion preventing layer may be less than about 3. Undoped materials may be deposited to form the diffusion preventing layer. The n-type impurities may include phosphorous.

According to at least one example embodiment, the substrate in the first region may be partially etched to form a recess for forming the gate. A gate oxide layer may be formed on the substrate.

In order to form a preliminary first conductive layer, a first polysilicon layer having a first impurity concentration may be formed to fill a portion of the recess and form the gate. A second polysilicon layer having a second impurity concentration lower than the first impurity concentration may be formed on the first polysilicon layer.

According to at least some example embodiments, because a PMOS transistor gate may include a diffusion preventing layer having an excellent surface morphology, diffusion of impurities may be prevented such that the threshold voltage of a PMOS transistor may be reduced and the threshold voltage distribution may be improved.

### BRIEF DESCRIPTION OF THE DRAWINGS

Example embodiments will be described with reference to the following figures, wherein like reference numerals refer to like parts throughout the various figures unless otherwise specified. In the figures:

FIG. 1 is a cross-sectional view illustrating a gate of PMOS transistor according to an example embodiment;

FIGS. 2 to 5 are cross-sectional views illustrating at least one method of forming the gate of the PMOS transistor in FIG. 1;

FIG. 6 is a cross-sectional view illustrating gates of a DRAM device according to an example embodiment;

FIGS. 7 to 13 are cross-sectional views illustrating at least one method of forming the gates in FIG. 6;

FIG. 14 is a surface image of an amorphous silicon layer in Example 1;

FIG. 15 is a surface image of an amorphous silicon layer in Comparative Example 1; and

FIG. 16 is a graph showing threshold voltages of PMOS transistors formed by Example 2 and Comparative Example 2.

### DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification; specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which the example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Example Embodiment I

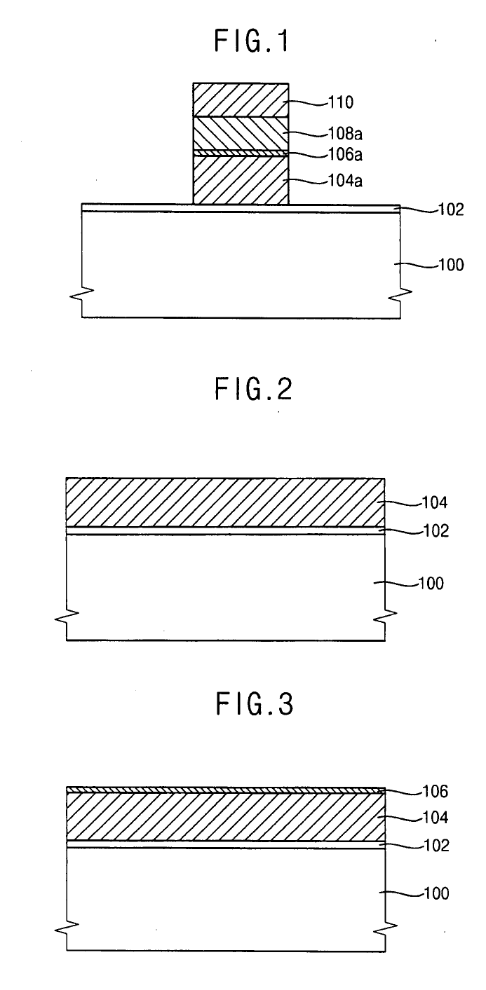

FIG. 1 is a cross-sectional view illustrating a gate of PMOS transistor in accordance with a first example embodiment.

Referring to FIG. 1, a substrate 100 that may include a semiconductor material such as silicon is prepared.

A gate oxide layer 102 may be formed on the substrate 100. In this example embodiment, the gate oxide layer 102 may include silicon oxide formed by thermally oxidizing a surface of the substrate 100. Alternatively, the gate oxide layer 102 may include silicon oxide having a nitridated surface. When the gate oxide layer 102 includes silicon oxide having a nitridated surface, ions or metal may be prevented from diffusing into the substrate 100 through the gate oxide layer 102.

A first conductive layer pattern 104a may be formed on the gate oxide layer 102. The first conductive layer pattern 104a may include polysilicon doped with boron.

A diffusion preventing layer pattern 106a may be formed on the first conductive layer pattern 104a to prevent diffusion of boron ions. The diffusion preventing layer pattern 106a may include amorphous silicon, which may be obtained by a chemical vapor deposition (CVD) process using a reaction gas that may include trisilane (Si₃H₈).

The diffusion preventing layer pattern 106a may be formed uniformly or approximately uniformly on approximately an entire upper face of the first conductive layer pattern 104a, such that weak points are not generated and the diffusion of boron ions is prevented. Particularly, when the root-mean-square roughness (RMSR) of a surface of the diffusion preventing layer pattern 106a is more than about 3, boron ions may diffuse easily through a thin portion of the diffusion preventing layer pattern 106a. Therefore, the root-mean-square roughness of the surface of the diffusion preventing layer pattern 106a including amorphous silicon preferably is less than 3.

On the other hand, the total resistance of the gate may be increased when the diffusion preventing layer pattern 106a has a thickness of more than 100 Å, whereas the diffusion of boron ions may not be effectively prevented when the diffusion preventing layer pattern 106a has a thickness of less than about 10 Å. Therefore, the diffusion preventing layer pattern 106a may preferably have a thickness of about 10 Å to about 100 Å.

A second conductive layer pattern 108a may be formed on the diffusion preventing layer pattern 106a. The second conductive layer pattern 108a may include a material having a resistance lower than that of the first conductive layer pattern 104a. For example, the second conductive layer pattern 108a may include a metal silicide material. In this example embodiment, the second conductive layer pattern 108a may include tungsten silicide.

Boron ions may diffuse through the second conductive layer pattern 108a including tungsten silicide about 10,000 times as fast as through the first conductive layer pattern 104a including polysilicon. However, because the diffusion preventing layer pattern 106a including amorphous silicon may have a root-mean-square roughness of less than about 3, the boron ions may be sufficiently prevented from diffusing from the first conductive layer pattern 104a to the second conductive layer pattern 108a.

A hard mask pattern 110 may be formed on the second conductive layer pattern 108a.

FIGS. 2 to 5 are cross-sectional views illustrating a method of forming a gate of a PMOS transistor according to the example embodiment shown in FIG. 1.

Referring to FIG. 2, a gate oxide layer 102 may be formed on a substrate 100 including a semiconductor material such as silicon.

The substrate may be thermally oxidized to form the gate oxide layer 102. For example, the gate oxide layer 102 may include silicon oxide. Alternatively, a surface of silicon oxide formed by a thermal oxidization process may be nitridated to form the gate oxide layer 102. Here, the gate oxide layer 102 may be formed by a process including, for example, a plasma nitridation process.

A preliminary first conductive layer (not illustrated) may be formed on the gate oxide layer 102. The preliminary first conductive layer may include polysilicon.

Undoped polysilicon may be deposited on the gate oxide layer 102 to form the preliminary first conductive layer. Alternatively, polysilicon doped with n-type impurities may be deposited on the gate oxide layer 102 to form the preliminary first conductive layer. For example, n-type impurities may include phosphorous (P), arsenic (As), antimony (Sb), etc. These may be used alone or in a mixture. In a case where the preliminary first conductive layer may include polysilicon doped with n-type impurities, n-type impurities may be doped into polysilicon by an in-situ process in the polysilicon deposition process.

Boron ions may be implanted as p-type impurities into the preliminary first conductive layer to form a first conductive layer 104. The first conductive layer 104 may include polysilicon doped with boron ions.

Referring to FIG. 3, undoped polysilicon may be deposited on the first conductive layer 104 to form a diffusion preventing layer 106.

The diffusion preventing layer 106 may serve to prevent boron ions doped in the first conductive layer 104 from diffusing into an upper layer. Here, when the diffusion preventing layer 106 may not have a uniform thickness, boron ions may easily diffuse through a relatively thin portion of the diffusion preventing layer 106 into the upper layer. Therefore, the diffusion preventing layer 106 may preferably be of an approximately uniform thickness.

The diffusion preventing layer 106 including amorphous silicon may be formed by a CVD process using a reaction gas that may include trisilane (Si₃H₈). The diffusion preventing layer 106 may be formed at a temperature of about 400° C. to about 600° C.

A surface of the diffusion preventing layer 106 formed using a reaction gas that may include trisilane (Si₃H₈) may have a root-mean-square roughness of less than about 3. Since the diffusion preventing layer 106 may have an excellent surface morphology, the diffusion preventing layer 106 may be formed to have an approximately uniform thickness on approximately an entire upper face of the first conductive layer 104 without generating weak points.

The diffusion preventing layer 106 may be about 10 Å to about 100 Å thick.

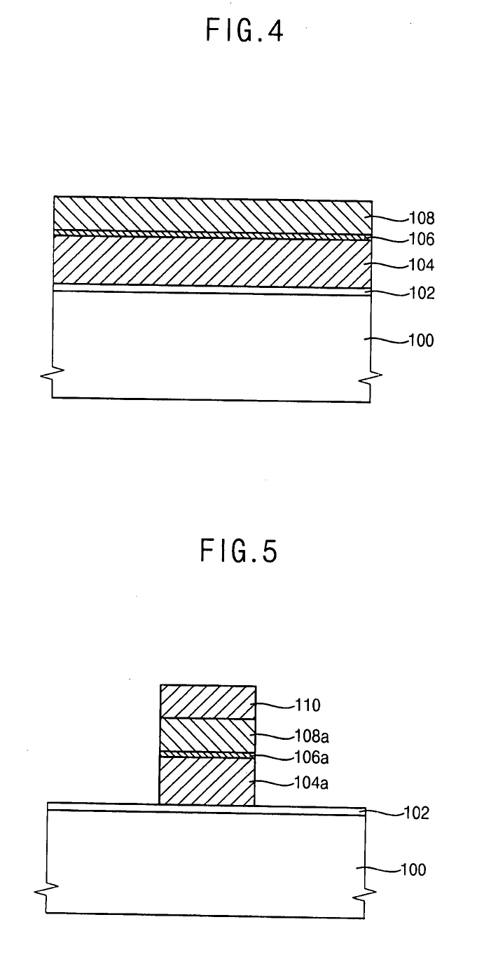

Referring to FIG. 4, a second conductive layer 108 may be formed on the diffusion preventing layer 106. The second conductive layer 108 may have a resistance lower than that of the first conductive layer 104. Metal silicide material may be deposited on the diffusion preventing layer 106 to form the second conductive layer 108. In this example embodiment, the second conductive layer 108 may include tungsten silicide.

Referring to FIG. 5, a hard mask pattern 110 may be formed on the second conductive layer 108. The second conductive layer 108, the diffusion preventing layer 106 and the first conductive layer pattern 104 may be successively etched using the hard mask pattern 110 as an etching mask to form a gate of a transistor that may include a second conductive layer pattern 108a, a diffusion preventing layer pattern 106a and a first conductive layer pattern 104a stacked on the gate oxide layer 102.

Although not illustrated in figures, while processes for forming the transistor are performed, the boron ions may continuously diffuse due to heat generated during those processes. That is, at least some of the boron ions doped in the first conductive layer pattern 104a may diffuse into the diffusion preventing layer pattern 106a that may be formed on the first conductive layer pattern 104a. Thus, undoped amorphous silicon of the diffusion preventing layer pattern 106a may be transformed into silicon doped with boron ions. Also, the amorphous silicon that may serve as the diffusion preventing layer pattern 106a may be transformed into crystalline silicon (i.e., polysilicon) by the continuous thermal processes. Accordingly, the diffusion preventing layer pattern 106a may become conductive, and electrically connect the first conductive layer pattern 104a to the second conductive layer pattern 108a.

However, the boron ions might not diffuse into the second conductive layer pattern 108a that may be formed on the diffusion preventing layer pattern 106a. Therefore, problems such as an increase of a threshold voltage and an irregular dispersion of the threshold voltage, which can be generated by diffusion of the boron ions into the second conductive layer pattern 108a, may be reduced.

Then, although not illustrated in figures, p-type impurities may be implanted into both sides of the gate to form source/drain regions and thus may complete a p-type transistor.

### Example Embodiment II

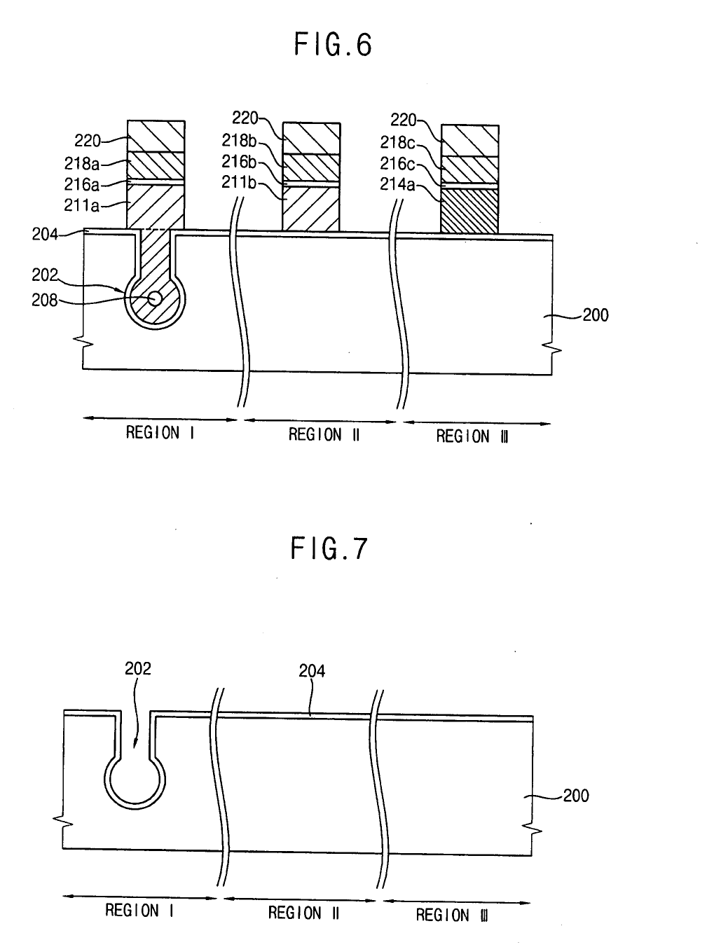

FIG. 6 is a cross-sectional view illustrating gates of a DRAM device in accordance with a second example embodiment.

The DRAM device described hereinafter may include at least one n-type transistor on a cell region, and at least an n-type transistor and/or a p-type transistor on a peripheral circuit region. Also, at least one n-type transistor on the cell region may include a recessed gate. The n-type transistor and the p-type transistor on the peripheral circuit region may each include a planar type transistor.

Referring to FIG. 6, a substrate 200 including a semiconductor material, such as silicon, may be prepared.

The substrate 200 may be divided into three regions. N-type transistors serving as a unit cell may be formed on a first region. N-type transistors serving as a peripheral circuit for driving the unit cell may be formed on a second region. P-type transistors serving as a peripheral circuit for driving the unit cell may be formed on a third region.

Here, a portion of the substrate 200 in the first region where a gate of a cell transistor may be formed may have a recess 202. A lower width of the recess 202 may be greater than an upper width of the recess 202. Also, upper sidewalls of the recess 202 may have an orientation substantially perpendicular to an upper face of the substrate 200. A lower portion of the recess 202 may have a hemisphere shape or an elliptical shape.

A gate oxide layer 204 may be formed on the substrate 200 including the recess 202. For example, the gate oxide layer 204 may include silicon oxide or silicon oxynitride. Alternatively, the gate oxide layer 204 may be formed using metal oxide having a high dielectric constant such as hafnium oxide, tantalum oxide, zirconium oxide, titanium oxide, aluminum oxide, etc.

A first lower conductive layer pattern 211a may be formed on the gate oxide layer 204 of the first region to fill the recess 202. The first lower conductive layer pattern 211a may protrude from the upper face of the substrate 200. The first lower conductive layer pattern 211a may include polysilicon doped with n-type impurities. In this example embodiment, the first lower conductive layer pattern 211a may include polysilicon doped with phosphorous.

A lower portion of the first lower conductive layer pattern 211a in the recess 202 may be doped with phosphorous having a first impurity concentration, whereas a upper portion of the first lower conductive layer pattern 211a protruding from the upper face of the substrate 200 may be doped with phosphorous having a second impurity concentration. This second impurity concentration may be lower than the first impurity concentration.

Because the recess 202 may be filled with the polysilicon doped to a relatively high concentration with n-type impurities, a void 208 may be prevented from being generated adjacent to the sidewalls of the recess 202.

A first diffusion preventing layer pattern 216a for preventing diffusion of boron ions may be formed on the first lower conductive layer pattern 211a. The diffusion preventing layer pattern 216a may prevent boron ions from diffusing along a grain boundary from the adjacent third region into the first region during processing.

The first diffusion preventing layer pattern 216a may include amorphous silicon, which may be obtained by a process such as CVD, for example, using a reaction gas that may include trisilane (Si₃H₈). The root-mean-square roughness of a surface of the first diffusion preventing layer pattern 216a that may include amorphous silicon may be preferably less than about 3. Additionally, the first diffusion preventing layer pattern 216a may preferably have a thickness of about 10 Å to about 100 Å.

A first upper conductive layer pattern 218a may be formed on the first diffusion preventing layer pattern 216a. The first upper conductive layer pattern 218a may include a material having a resistance lower than that of the first lower conductive layer pattern 211a. For example, the first upper conductive layer pattern 218a may include metal silicide material. In this example embodiment, the first upper conductive layer pattern 218a may include tungsten silicide.

A second lower conductive layer pattern 211b may be formed on the gate oxide layer 204 in the second region. The second lower conductive layer pattern 211b may include polysilicon doped with n-type impurities.

A second layer pattern 216b for preventing diffusion of boron ions may be formed on the second lower conductive layer pattern 211b. The second diffusion preventing layer pattern 216b may include a material and a structure similar to those of the first diffusion preventing layer pattern 216a.

A second upper conductive layer pattern 218b may be formed on the second diffusion preventing layer pattern 216b. The second upper conductive layer pattern 218b may include a material having a resistance lower than that of the second lower conductive layer pattern 211b. The second upper conductive layer pattern 218b may include a material and a structure substantially the same as those of the first upper conductive layer pattern 218a.

A third lower conductive layer pattern 214a may be formed on the gate oxide layer 204 in the third region. The third lower conductive layer pattern 214a may include polysilicon doped with p-type impurities such as boron ions.

A third layer pattern 216c for preventing diffusion of boron ions may be formed on the third lower conductive layer pattern 214a. The third diffusion preventing layer pattern 216c may include amorphous silicon, which may obtained by CVD or a similar process using a reaction gas that may include trisilane (Si₃H₈). The root-mean-square roughness of a surface of the third diffusion preventing layer pattern 216c including amorphous silicon may be preferably less than about 3. Also, the third diffusion preventing layer pattern 216c may preferably have a thickness of about 10 Å to about 100 Å.

A third upper conductive layer pattern 218c may be formed on the third diffusion preventing layer pattern 216c. The third upper conductive layer pattern 218c may include a material having a resistance lower than that of the third lower conductive layer pattern 214a. The third upper conductive layer pattern 218c may include a material and a structure substantially the same as those of the first and second upper conductive layer patterns 218a and 218b.

A hard mask pattern 220 may be formed on the first, second and/or third conductive layer patterns 218a, 218b and 218c.

FIGS. 7 to 13 are cross-sectional views illustrating at least one method of forming the gates in FIG. 6.

Referring to FIG. 7, a substrate 200, including a semiconductor material such as silicon, may be prepared. The substrate 200 may be divided into a first region, a second region and a third region. N-type transistors serving as a unit cell may be formed on the first region. N-type transistors serving as a peripheral circuit for driving the unit cell may be formed on the second region. P-type transistors serving as a peripheral circuit for driving the unit cell may be formed on the third region.

A shallow trench isolation (STI) process may be carried out on the substrate 200 to define an active region (not illustrated) of the substrate 200 in which elements may be formed.

Portions of the substrate 200 in the active region of the first region where a gate of a cell transistor may be formed may be partially etched to form a recess 202.

A first mask pattern (not illustrated) may be formed on the substrate 200 to selectively expose the portion where the recess may be formed. The exposed substrate 200 may be anisotropically etched to form a preliminary recess (not illustrated). Then, a second mask pattern (not illustrated) for selectively masking sidewalls of the preliminary recess may be formed on the substrate 200. The exposed preliminary recess may be isotropically etched using the first and the second mask patterns as an etching mask to form the recess 200.

A lower width of the recess 202 may be greater than an upper width of the recess 202. Also, upper sidewalls of the recess 202 may have an orientation substantially perpendicular to an upper face of the substrate 200. A lower portion of the recess 202 may have a hemisphere shape or an elliptical shape.

A gate oxide layer 204 may be formed on the substrate 200 and inner faces of the recess 202. The gate oxide layer 204 may be formed by a thermal oxidation process. Further, an additional nitridation process may be performed on silicon oxide formed by the thermal oxidation process, to thereby form the gate oxide layer 204. The additional nitridation process may include a plasma nitridation process. Alternatively: the gate oxide layer 204 may be formed using a metal oxide having a dielectric constant higher than that of silicon oxide such as hafnium oxide, tantalum oxide, zirconium oxide, titanium oxide, aluminum oxide, etc.

An undoped polysilicon layer (not illustrated) may be formed on the gate oxide layer 204. The undoped polysilicon layer may have a thickness of about 30 Å to about 100 Å from the substrate 200 including the recess 202. The undoped polysilicon layer can serve as a buffer layer to prevent the diffusion of doped impurities, which may be doped in a first polysilicon layer formed later, into the gate oxide layer 204. However, the process for forming the undoped polysilicon layer may be omitted to avoid redundancy.

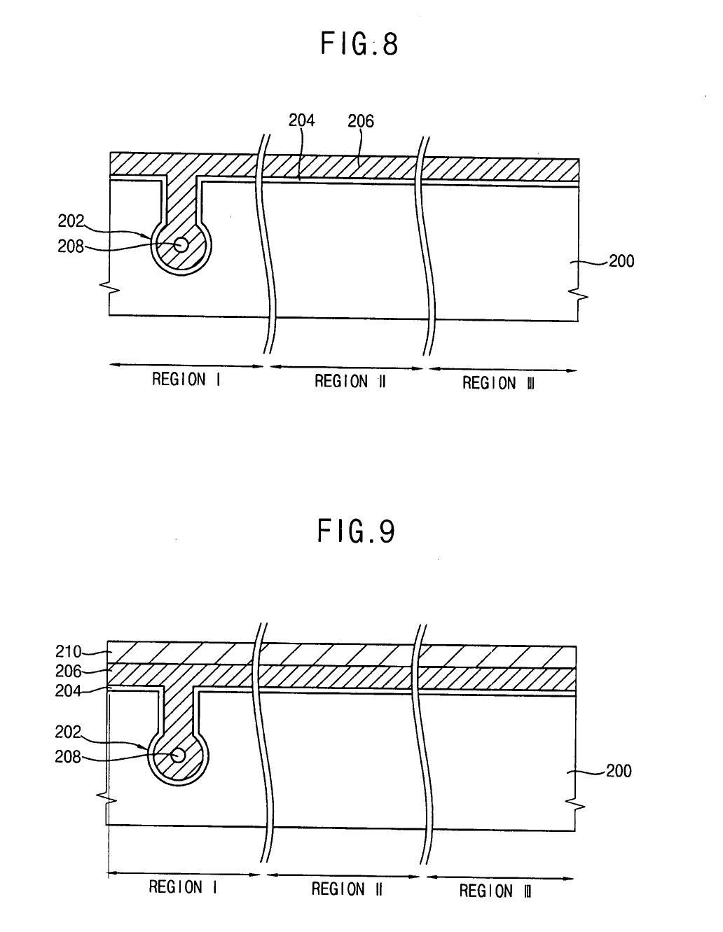

Referring to FIG. 8, a first preliminary polysilicon layer 206 doped with n-type impurities may be formed on the gate oxide layer 204. The first preliminary polysilicon layer 206 may be formed by a low pressure chemical vapor deposition (LPCVD) process.

Here, the first preliminary polysilicon layer 206 may completely block the recess 202. In addition, a void 208 may be formed in a central portion of the recess 202.

The first preliminary polysilicon layer 206 may be doped with impurities at a sufficient concentration to prevent the void 208 from moving into the sidewalls of the recess 202 during a subsequent process.

For example, the first preliminary polysilicon layer 206 may be doped with impurities such as phosphorous. Phosphorous may be doped using a doping gas that may include phosphine (PH₃).

Referring to FIG. 9, a second preliminary polysilicon layer 210 may be formed on the first preliminary polysilicon layer 206. The second preliminary polysilicon layer 210 may be doped with n-type impurities at a concentration lower than that of the first preliminary polysilicon layer 206. Since the first preliminary polysilicon layer 206 may block the recess 202, the second preliminary polysilicon layer 210 might not be formed in the recess 202.

The second preliminary polysilicon layer 210 may be formed by an in-situ process without a vacuum break in the same chamber where the first preliminary polysilicon layer 206 may be formed. Accordingly, the second preliminary polysilicon layer 210 may be formed using substantially the same doping gas as may be used for forming the first preliminary polysilicon layer 206. For example, the second preliminary polysilicon layer may be formed using less phosphine (PH₃) than might be used for forming the first preliminary polysilicon layer 206.

When a preliminary polysilicon layer may be doped with n-type impurities at a high concentration, p-type impurities may need to be excessively implanted into a region of the preliminary polysilicon layer where the gate of the p-type transistor might be formed by a subsequent process. However, since an upper preliminary polysilicon layer may be doped with n-type impurities at a concentration lower than that of a lower preliminary polysilicon layer, p-type impurities may need not be excessively implanted into the upper preliminary polysilicon layer when a PMOS transistor may be formed in the third region by a subsequent process.

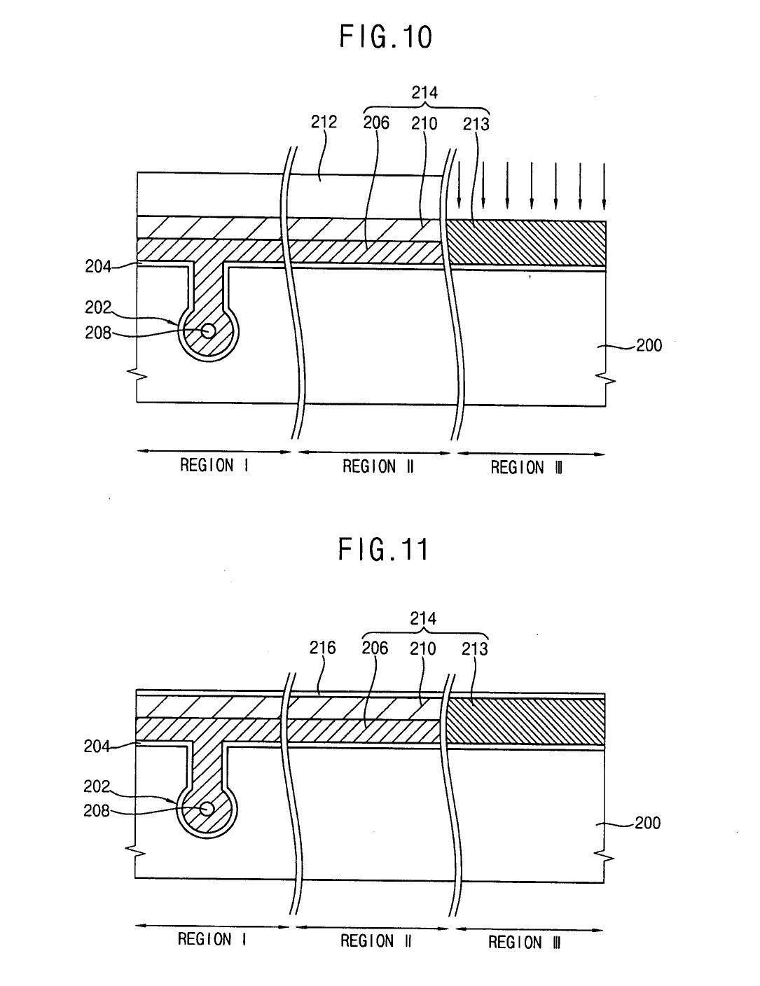

Referring to FIG. 10, a photoresist pattern 212 may be formed on the substrate 200 to expose an upper surface of the second preliminary polysilicon layer 210 in the third region. P-type impurities may be implanted into the exposed first and second preliminary polysilicon layers 206 and 210 using the photoresist pattern 210 as an ion implanting mask. In this example embodiment, boron ions may be implanted by an ion implantation process that may use phosphine (PH₃).

P-type impurities may be selectively doped into the exposed first and second preliminary polysilicon layers 206 and 210 by the ion implantation process to complete a first conductive layer 214. The first conductive layer 214 may include first and second preliminary polysilicon layers 206 and 210 doped with n-type impurities in the first and second regions. The first conductive layer 214 may include a polysilicon layer 213 doped with boron in the third region.

Referring to FIG. 11, a diffusion preventing layer 216 for preventing diffusion of boron ions may be formed on the first conductive layer 214. Undoped amorphous polysilicon may be deposited on the first conductive layer 214 to form the diffusion preventing layer 216.

Particularly, the diffusion preventing layer 216 may be formed by CVD, or a similar, process using a reaction gas that may include trisilane (Si₃H₈). The diffusion preventing layer 216 may be formed at a temperature of about 400° C. to about 600° C. The root-mean-square roughness of a surface of the diffusion preventing layer 216 that may be formed by the process may be less than about 3. Since the diffusion preventing layer 216 may have excellent surface morphology, the diffusion preventing layer 216 may be formed to have an approximately uniform thickness on approximately an entire upper face of the first conductive layer 214 without generating weak points.

The diffusion preventing layer 216 may have a thickness of about 10 Å to about 100 Å.

A thermal treatment process may be performed on the first conductive layer 214 to activate the doped impurities. In this example embodiment, the activation process for activating the impurities may be performed at a temperature of about 800° C. to about 1000° C. for about 10 to about 50 seconds by a rapid thermal treatment. By the activation process, n-type and p-type impurities may diffuse into a polysilicon layer (not illustrated) that may be formed on the gate oxide layer 202.

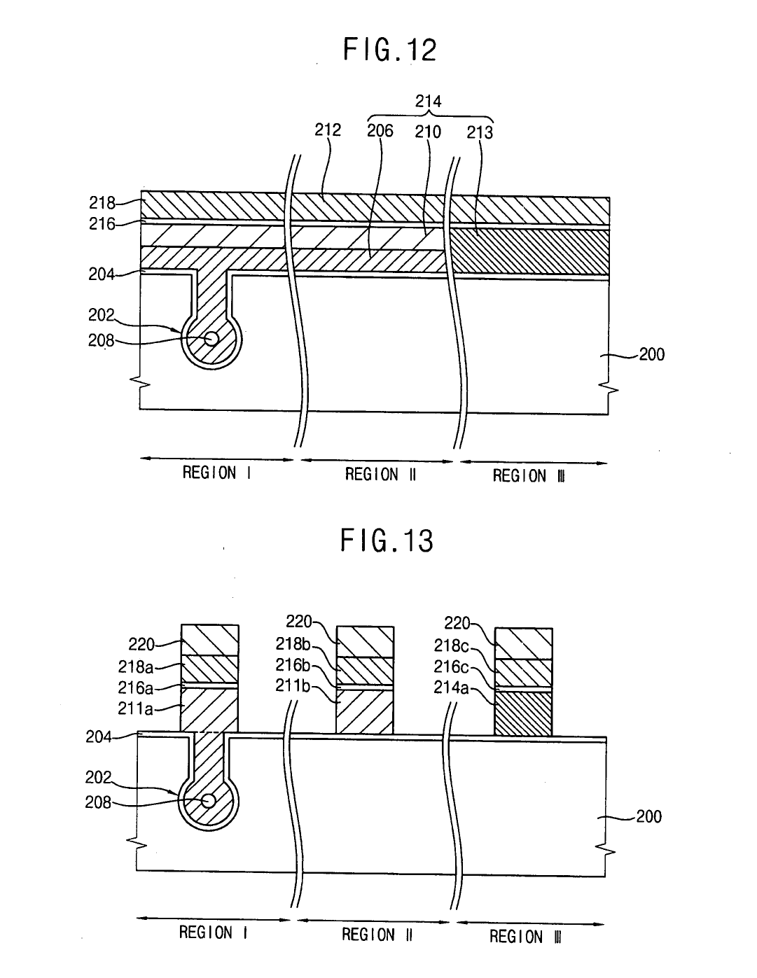

Referring to FIG. 12, an upper conductive layer 218 may be formed on the diffusion preventing layer 216. The upper conductive layer 218 may have a resistance lower than that of the first conductive layer 214. The upper conductive layer 218 may be a metal silicide layer. In this example embodiment, tungsten silicide may be deposited on the diffusion preventing layer 216 to form the upper conductive layer 218.

Referring to FIG. 13, hard mask patterns 220 may be formed on the upper conductive layer 218. The hard mask patterns 220 may be used as masks for forming gates in the first, second and/or third regions.

The upper conductive layer 218, the diffusion preventing layer 216 and the lower conductive layer 214 may be etched using the hard mask patterns 220 as etching masks to form gates in the first, second and third regions.

The first gate may be formed in the first region on the substrate 200. The first gate may have a structure where a first lower conductive layer pattern 211a, a first diffusion preventing layer pattern 216a and a first upper conductive layer pattern 218a may be successively stacked on the substrate 200. Here, the first lower conductive layer pattern 211a may be formed on the gate oxide layer 204 in the first region. Also, the first lower conductive layer pattern 211a may fill up the recess 202 and may protrude from the upper surface of the substrate 200.

The second gate may be formed in the second region on the substrate 200. The second planar type gate may have a structure where a second lower conductive layer pattern 211b, a second diffusion preventing layer pattern 216b and a second upper conductive layer pattern 218b may be successively stacked on the substrate 200. The first and the second lower conductive layer patterns 211a and 211b may include polysilicon doped with n-type impurities.

The third gate may be formed in the third region on the substrate 200. The third planar type gate may have a structure where a third lower conductive layer pattern 214a, a third diffusion preventing layer pattern 216c and a third upper conductive layer pattern 218c may be successively stacked on the substrate 200. Here, the third lower conductive layer pattern 214a may include polysilicon doped with p-type impurities.

Unit processes such as deposition processes for the upper conductive layer 218 and the hard mask layer 220, a developing process, an etching process, etc., may be performed at a high temperature to allow the impurities in the first conductive layer 214 to diffuse into other layers. Thus, during the unit processes, impurities in the first conductive layer 214 may continuously diffuse such that the concentration of impurities may be altered.

Accordingly, the first lower conductive layer pattern 211a may include a first polysilicon pattern doped with impurities at a first concentration and a second polysilicon pattern doped with impurities at a second concentration that may be lower than the first concentration. The first polysilicon pattern may be positioned within the recess 202, and the second polysilicon pattern may protrude from the upper surface of the substrate 200. The second lower conductive layer pattern 211b may be doped with impurities at the second concentration.

In this example embodiment, the cell transistor may include the gate having the recessed shape. Alternatively, the cell transistor may include a planar type gate. In the case where the cell transistor may include the planar type gate, the first lower conductive layer pattern in the first region may include polysilicon doped with n-type impurities at substantially the same concentration as in the second region.

Experiment Concerning Morphology of an Amorphous Silicon Layer

### Example 1

An amorphous silicon layer was formed on a bulk substrate using a reaction gas including trisilane (Si₃H₈) by a chemical vapor deposition (CVD) process.

### Comparative Example 1

An amorphous silicon layer was formed on a bulk substrate using a reaction gas including silane (SiH₄) by a CVD process.

Surface images with respect to the amorphous silicon layers in Example 1 and Comparative Example 1 were obtained using an atomic force microscope (AFM).

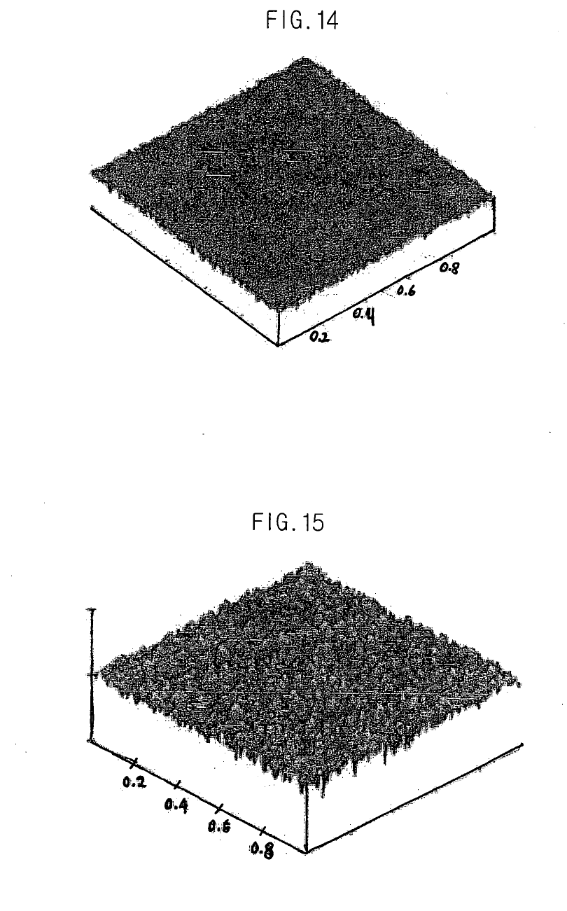

FIG. 14 is a surface image of the amorphous silicon layer in Example 1, and FIG. 15 is a surface image of the amorphous silicon layer in Comparative Example 1.

Comparing the surface image in FIG. 14 with the surface image in FIG. 15, surface morphology the amorphous silicon layer in Example 1 may be better than that of the amorphous silicon layer in Comparative Example 1. In particular, when the amorphous silicon layer in Example 1 was deposited to have a thickness of about 30 A to about 100 Å, root-mean-square roughness of the surface thereof was less than 3.

Therefore, a diffusion preventing layer having an approximately uniform surface may be formed by a method in accordance with the present invention.

Experiment Concerning a Threshold Voltage of PMOS Transistor

### Example 2

A gate of a p-type transistor was formed on a substrate according to the first example embodiment. The gate had a structure where a gate oxide layer, a first conductive layer pattern, a diffusion preventing layer pattern and a second conductive layer pattern were successively stacked on the substrate. A gate oxide layer was formed on the substrate, and the first conductive layer pattern was formed on the gate oxide layer. The first conductive layer pattern included polysilicon doped with boron ions. The diffusion preventing layer included amorphous silicon formed by a CVD process using a reaction gas including trisilane (Si₃H₈). The second conductive layer pattern included tungsten silicide.

Source/drain regions were formed in the substrate at both sides of the gate.

### Comparative Experiment 2

A gate was formed on a substrate. The gate had a structure where a gate oxide layer, a first conductive layer pattern including polysilicon doped with boron ions and a second conductive layer including tungsten silicide were successively stacked on the substrate. Source/drain regions were formed in the substrate at both sides of the gate.

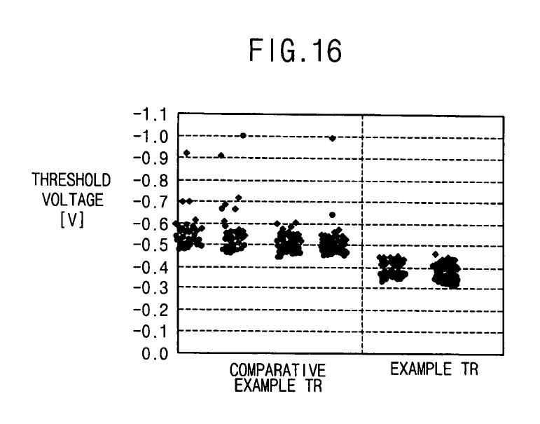

FIG. 16 is a graph showing threshold voltages of PMOS transistors formed by Example 2 and Comparative Example 2.

Referring to FIG. 16, threshold voltages of PMOS transistors formed in Example 2 ranged from about −0.35V to about −0.45V, with a relatively narrow and consistent degree of scattering. In contrast, threshold voltages of PMOS transistors formed by Comparative Example 2 ranged from about −0.5V to about −0.6V, with an irregular and wide threshold voltage distribution.

Therefore, the diffusion preventing layer may reduce absolute values of the threshold voltages of PMOS transistors. The diffusion preventing layer having an excellent surface morphology may effectively prevent diffusion of boron ions, such that a PMOS transistor having a low threshold voltage may be formed.

According to the present invention, since a PMOS transistor gate may include a diffusion preventing layer having excellent surface morphology, diffusion of impurities may be sufficiently prevented. Thus, threshold voltages of PMOS transistors may be reduced, and threshold voltage distribution may be improved.

The foregoing is illustrative of example embodiments and is not to be construed as limiting thereof. Although example embodiments have been described, those skilled in the art will readily appreciate that many modifications are possible in the example embodiments without materially departing from the novel teachings and advantages of example embodiments. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A gate of a transistor, comprising:
a gate oxide layer formed on a substrate;
a first conductive layer pattern formed on the gate oxide layer, the first conductive layer pattern including polysilicon doped with boron;
a diffusion preventing layer pattern formed on the first conductive layer pattern, the diffusion preventing layer pattern including amorphous silicon; and
a second conductive layer pattern formed on the diffusion preventing layer pattern, the second conductive layer pattern including metal silicide.

2. The gate of claim 1, wherein root-mean-square roughness of a surface of the diffusion preventing layer pattern is less than 3.

3. The gate of claim 1, wherein the diffusion preventing layer pattern has a thickness of 10 Å to 100 Å.

4. The gate of claim 1, wherein the metal silicide includes tungsten silicide.

5. The gate of claim 1, wherein
the substrate and gate oxide layer are divided into a first region and a second region;
the first conductive layer pattern includes polysilicon doped with n-type impurities in the first region and doped with boron in the second region; and
the second conductive layer pattern, the diffusion preventing layer and the first conductive layer form a first gate electrode structure including polysilicon doped with n-type impurities in the first region and a second gate electrode structure including polysilicon doped with boron in the second region.

6. The gate of claim 5, wherein root-mean-square roughness of a surface of the diffusion preventing layer pattern is less than 3.

7. The gate of claim 5, wherein the diffusion preventing layer pattern has a thickness of 100 Å to 100 Å.

8. The gate of claim 5, wherein the metal silicide includes tungsten silicide.

9. The gate of claim 5, wherein the substrate includes a recess in the first region.

10. A method of forming a gate of a transistor, comprising:
forming a gate oxide layer on a substrate;
forming a first conductive layer including polysilicon doped with boron on the gate oxide layer;
forming a diffusion preventing layer including amorphous silicon on the first conductive layer by a chemical vapor deposition process using a reaction gas including trisilane (Si₃H₈);
forming a second conductive layer including metal silicide on the diffusion preventing layer; and
patterning the second conductive layer, the diffusion preventing layer and the first conductive layer to form a gate electrode structure.

11. The method of claim 10, wherein root-mean-square roughness of a surface of the diffusion preventing layer is less than 3.

12. The method of claim 10, wherein forming the diffusion preventing layer includes forming the diffusion preventing layer at a thickness of about 10 Å to about 100 Å.

13. The method of claim 10, wherein forming the diffusion preventing layer includes forming the diffusion preventing layer using an undoped material.

14. The method of Claim 10, wherein forming the diffusion preventing layer includes heating the diffusion preventing layer at a temperature of 400° C. to 600° C.

15. A method of forming a gate of a transistor, comprising:
forming a gate oxide layer on a substrate, the substrate divided into a first region and a second region;
forming a preliminary first conductive layer including polysilicon doped with n-type impurities on the gate oxide layer;
implanting boron ions into the preliminary first conductive layer in the second region to form a first conductive layer;
forming a diffusion preventing layer including amorphous silicon on the first conductive layer by a chemical vapor deposition process;
forming a second conductive layer including metal silicide on the diffusion preventing layer; and
patterning the second conductive layer, the diffusion preventing layer and the first conductive layer to form a first gate electrode structure including polysilicon doped with n-type impurities in the first region and a second gate electrode structure including polysilicon doped with boron in the second region.

16. The method of claim 15, wherein the forming the diffusion preventing layer includes forming the diffusion preventing layer at a thickness of 10 Å to 100 Å.

17. The method of claim 15, wherein root-mean-square roughness of a surface of the diffusion preventing layer is less than 3.

18. The method of claim 15, wherein forming the diffusion preventing layer includes forming the diffusion preventing layer using an undoped material.

19. The method of claim 15, wherein the n-type impurities include phosphorous.

20. The method of claim 15, further comprising:
partially etching the substrate in the first region to form a recess for forming the gate, before forming, the gate oxide layer.

21. The method of claim 20, wherein forming the preliminary first conductive layer includes:
forming a first polysilicon layer doped with impurities at a first concentration to fill up the recess for forming the gate; and
forming a second polysilicon layer doped with impurities at a second concentration lower than the first concentration on the first polysilicon layer.
